(19) United States
(12) Patent Application Publication
(10) Pub. No.: US 2004/0188242 A1
(43) Pub. Date: Sep. 30, 2004

(54) Method of manufacturing electromagnetic interference shield

(76) Inventor: Ga-Lane Chen, Fremont, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/813,409

(22) Filed: Mar. 29, 2004

(30) Foreign Application Priority Data
Mar. 28, 2003 (TW) 92107182

(51) Int. Cl. C23C 14/32

(52) U.S. Cl. 204/192.15; 204/192.17

(57) ABSTRACT

A method of manufacturing an electromagnetic interference shield (3) includes the steps of: preparing a substrate (30) and at least one target module (1), and mounting them in a sputtering chamber (100), wherein each target module has a target (10) bonded thereto, and the target is made from an electrically conductive material; evacuating the sputtering chamber to a predetermined degree of vacuum; introducing a working gas into the sputtering chamber to a predetermined gas pressure level; applying a voltage to the target module using a power supply (2), thus activating a magnetron sputtering process between the target module and the substrate, and depositing at least one electrically conductive layer (31) from the target module onto the substrate until a desired thickness is achieved on the substrate.

### BACKGROUND OF THE INVENTION

1. Field of the Invention

The present invention relates to a method of manufacturing shields for reducing electromagnetic interference from electronic instruments, and particularly to manufacturing electromagnetic interference shields using a magnetron sputtering process.

2. Description of Related Art

Electromagnetic interference (EMI) is a well known problem with electronic devices. Electromagnetic radiation penetrating the device may cause electronic failure, and electromagnetic radiation emitted into the atmosphere may cause environmental pollution. Proper design is necessary to prevent the device's function from being disrupted by emissions from external sources and to minimize its system's emissions. Current methods for shielding against electromagnetic interference (EMI) include the use of metal housings, metal filled polymer housings, metal liners for housings, and conductive coatings for the interior of rigid polymer or composite housings.

Since plastics offer increased design flexibility and productivity with decreased cost, plastics will be more and more widely used for manufacturing electromagnetic interference shields. A variety of technologies using metal/plastic combinations and composites are being used as a shielding material in electronic devices, such as metal-filled resins for injection molding, conductive polymer resin for molding, and metal coating using plating. However, metal-filled resins for injection molding suffer from poor conductivity compared to metals. The conductive polymer resin is very expensive and complex shape molding is difficult from flow and uniformity perspectives. The major disadvantages of plating are its high cost, complex process cycles, and its application being limited to only certain polymer resins. Furthermore, it is difficult to form a uniform metal coating on polymer resin using the plating process, particularly on polymer resin having an even surface or recesses on its surface. Additionally, the formed metal coating cannot tightly adhere to the polymer resin using conventional methods.

Therefore, an improved method of manufacturing an electromagnetic interference shield is desired which overcomes the disadvantages of the prior art.

### SUMMARY OF THE INVENTION

A main object of the present invention is to provide a more effective method of manufacturing an electromagnetic interference shield, wherein a formed electrically conductive coating of the electromagnetic interference shield uniformly covers and strongly adheres to the surface of a substrate of the electromagnetic interference shield.

A method of manufacturing an electromagnetic interference shield comprises the steps of: preparing a substrate and at least one target module, and mounting them in a sputtering chamber, wherein each target module has a target bonded thereto, the target being made from an electrically conductive material; evacuating the sputtering chamber to a predetermined degree of vacuum; introducing a working gas into the sputtering chamber to a predetermined gas pressure level; applying a voltage to the target module using a power supply, thus activating a magnetron sputtering process between the target module and the substrate, and depositing at least one electrically conductive layer from the target module onto the substrate until a desired thickness is achieved on the substrate.

Other objects, advantages and novel features of the invention will become more apparent from the following detailed description of a preferred embodiment thereof when taken in conjunction with the accompanying drawings, wherein:

### BRIEF DESCRIPTION OF THE DRAWINGS

FIG. 1 is a schematic side view of an electromagnetic interference shield in accordance with a preferred embodiment of the present invention; and

FIG. 2 is a schematic diagram of an arrangement for manufacturing the electromagnetic interference shield of FIG. 1.

### DETAILED DESCRIPTION OF THE INVENTION

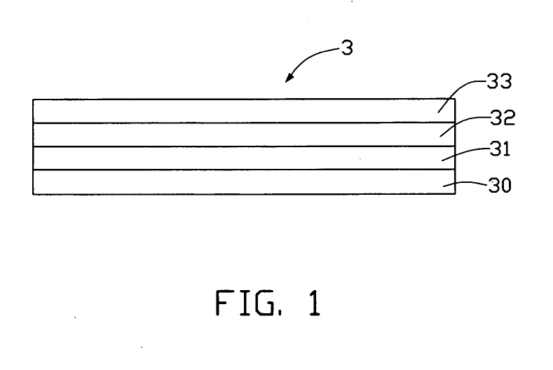

Referring now to the drawings in detail, FIG. 1 shows an electromagnetic interference shield 3 made by a method in accordance with a preferred embodiment of the present invention. The electromagnetic interference shield 3 comprises a resin substrate 30, a first metal layer 31, a second metal layer 32 and a third metal layer 33. The metal layers 31, 32, 33 are sequentially laminated on the resin substrate 30.

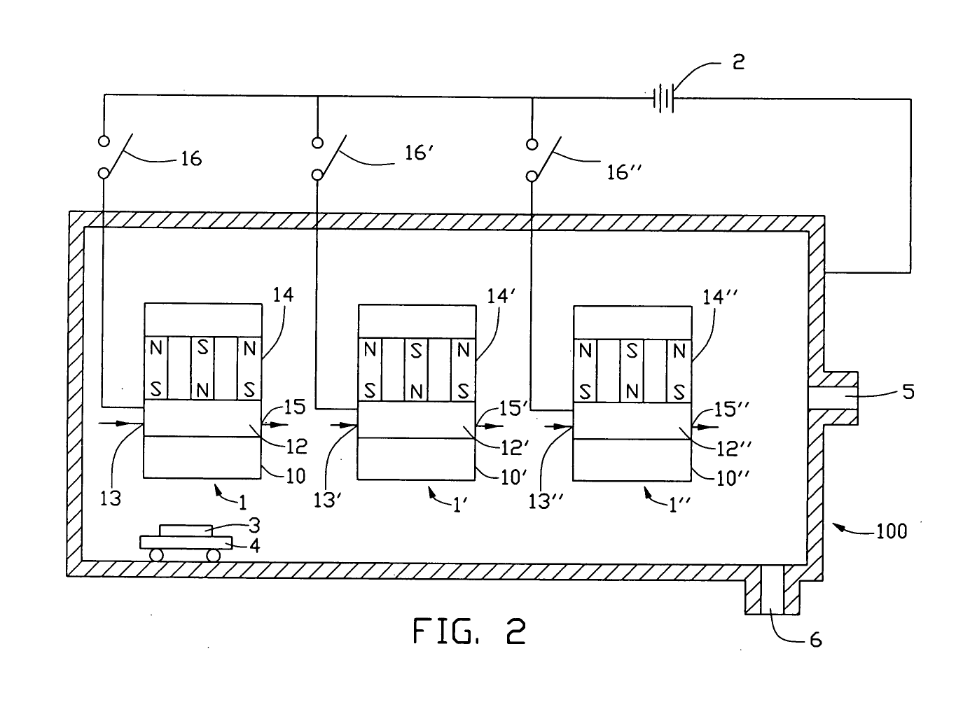

Referring to FIG. 2, an arrangement for manufacturing the electromagnetic interference shield 3 has a sputtering chamber 100. The sputtering chamber 100 has a gas inlet 5 and a vacuum port 6 connected with a vacuum system (not shown). Target modules 1, 1′, 1″ and a support 4 are set in the sputtering chamber 100. The target modules 1, 1′, 1″ connect with a power supply 2 respectively through switches 16, 16′, 16″. Each of target modules 1, 1′, 1″ includes a target 10, 10′ or 10″, a cathode 12, 12′ or 12″, and a magnetic field supply 14, 14′ or 14″. The magnetic field supplies 14, 14′ or 14″ may be magnets. The targets 10, 10′, 10″ are respectively bonded to the cathodes 12, 12′, 12″, and the cathodes 12, 12′, 12″ are mounted on the magnetic field supplies 14, 14′, 14″ and connect with the power supply 2 through the switches 16, 16′, 16″. The cathodes 12, 12′, 12″, which are further used for cooling the targets 10, 10′, 10″ during sputtering, may be copper plates, each having a coolant passage therethrough and having a coolant inlet 13, 13′ or 13″ and a coolant outlet 15, 15′ or 15″. The method of manufacturing the electromagnetic interference shield 3 comprises the steps of:

(1) preparing the resin substrate 30 and target modules 1, 1′, 1″ , and mounting them in the sputtering chamber 100;

(2) evacuating the sputtering chamber 100 to a degree of vacuum in a range between 10⁻⁸ and 10⁻⁴ torr using the vacuum port 6 and the vacuum system;

(3) introducing a working gas into the sputtering chamber 100 to a gas pressure level between 10⁻³ and 10⁻¹ torr through the gas inlet 5;

(4) alternately applying a voltage to the target modules 1, 1′, 1″ using a power supply 2, thus activating a magnetron sputtering process between the target modules 1, 1′, 1″ and the resin substrate 30, thus sequently depositing the metal layers 31, 32, 33 from the target modules 1, 1′, 1″ onto the resin substrate 30 until a desired thickness is achieved on the resin substrate 30.

In the first step, the resin substrate 30 is formed using a conventional process such as injection molding, extruding, or drawing. The resin may have at least one component selected from the group of polyvinyl chloride, polyethylene terephthalate, acrylonitrile-butadiene-styrene, polycarbonate, polyimide, polyetherimide, polyphenylene sulfide, polysulfone, polystyrene, glycol-modified polyester, polypropylene, and liquid crystal polymers. In this embodiment, the targets 10, 10′, 10″ are respectively a nickel (Ni) target, a copper (Cu) target and a stainless steel target. The targets 10, 10′, 10″ are formed using known methods of the art. After the targets 10, 10′, 10″ are formed and respectively mounted them on the cathodes 12, 12′, 12″, then the target modules 1, 1′, 1″ are available for magnetron sputtering. At this time, the switches 16, 16′, 16″ are open and the targets 10, 10′, 10″ are shielded by target shields (not shown) from being damaged or corroded. The resin substrate 30 is mounted on the support 4, keeping a predetermined distance between the substrate 30 and the targets 10, 10′, 10″. The support 4 can move freely along a plane facing the targets 10, 10′, 10″ and can be retained in the sputtering area of each target 10, 10′, 10″.

After the target modules 1, 1′, 1″ and the resin substrate 30 are mounted in the sputtering chamber 100, the sputtering chamber 100 is evacuated by means of the vacuum port 6 and the vacuum system (not shown) until the level of vacuum therein is between 10⁻⁸ and 10^{31 4} torr. Subsequently, the working gas is introduced into the sputtering chamber 100 through the gas inlet 5 at a flow rate between 2 and 80 SCCM (Standard Cubic Centimeter per Minute), until the gas pressure in the chamber 100 is maintained in the range of 10⁻³ to 10⁻¹ torr. In this embodiment, the working gas is argon. Other working gases can be used if desired. During the following sputtering process, the gas pressure in the chamber 100 is maintained in the range of 10⁻³ to 10⁻¹ torr, and argon can be supplied therein for maintaining the pressure level.

When the pressure in the chamber 100 gets to a predetermined value, the first switch 16 is closed and the shield on the target 10 is removed, thus applying a voltage between the target module 1 and the resin substrate 30 through the power supply 2. Herein, the substrate 30 is in the sputtering area of the target 10. In this embodiment, the power supply 2 is a direct current power source, the target bias voltage is in a range of 250 to 1000 volts, and a power density of the target 10 is in a range of 20 to 70 W/cm². As a consequence, a plasma of argon is activated between the target module 10 and the resin substrate 30. The argon ions strike the target 10 with sufficient energy to cause the ejection of atoms of Ni from the target 10 and deposition on the resin substrate 30 as the first metal layer 31. During the sputtering, a coolant, such as cool water, is circulated in the coolant passage from the inlet 13 to the outlet 15 for cooling the target 10 and keeping the temperature of the target 10 under 50 degrees centigrade, perfectly under 25 degrees centigrade.

When the first metal layer 31 is deposited to a predetermined thickness, for instance, a thickness from 50 to 120 angstroms, the switch 16 is opened, the target 10 is shielded again, the cooling process is stopped, and the sputtering process of Ni is shut off. Subsequently, the substrate 30 is moved to the sputtering area of the target 10′, the shield of the target 10′ is removed, a coolant is circulated in the coolant passage from the inlet 13′ to the outlet 15′ for cooling the target 10′ and keeping the temperature of the target 10′ under 50 degrees centigrade and perfectly under 25 degrees centigrade, and the switch 16′ is closed, thus applying a target bias voltage between 200 and 900 volts to the target 10′ and achieving a power density of the target 10′ in a range of 20 to 60 W/cm², which initiates a magnetron sputtering process of the Cu target for depositing the second metal layer 32 of Cu on the first metal layer 31 of the substrate 30.

When the second metal layer 32 is deposited to a predetermined thickness, for instance, a thickness from 4000 to 6000 angstroms, the switch 16′ is opened, the target 10′ is shielded again, the cooling process is stopped, thus shutting off the sputtering process of Cu. Then, the substrate 30 is moved to the sputtering area of the target 10″, the shield of the target 10″ is removed, a coolant is circulated in the coolant passage from the inlet 13″ to the outlet 15″ for cooling the target 10″ and keeping the temperature of the target 10″ under 50 degrees centigrade and perfectly under 25 degrees centigrade, and the switch 16″ is closed, applying a target bias voltage between 200 and 900 volts to the target 10′″ and achieving a power density of the target 10″ in a range of 20 to 60 W/cm², which initiates a magnetron sputtering process of the stainless steel target for depositing the third metal layer 33 of stainless steel on the second metal layer 32 of the substrate 30 until a predetermined thickness of the stainless steel is obtained, for instance, a thickness from 200 to 1000 angstroms.

During the sputtering process of the different target materials (i.e. Ni, Cu, and stainless steel), the resin substrate 30 may be cooled by a circulating coolant in a well known manner for protecting the substrate 30 from being damaged by heat or by the striking force of the ions.

Residual gas is then expelled from the chamber 100 until the temperature in the chamber 100 reaches below 25 degrees centigrade. Then the resin substrate 30 with deposited layers 31, 32, 33 is taken out of the chamber 100. Thus the desired electromagnetic interference shield 3 of the present invention is obtained.

In another embodiment, just one target module 1 is used, wherein the target 10 is a composite target made from Ni, Cu and stainless steel. The target 10 is divided into three portions, that is, a Ni portion, a Cu portion, and a stainless steel portion. Each portion may be kept a predetermined distance apart from the other portions. During the magnetron sputtering process, the target 10 can be turned an angle or the substrate 30 can be moved to a different side of the target 10 so that the corresponding target materials on the substrate 30 are deposited in their desired order to their desired thicknesses. Other conditions correspond to the foregoing process.

The metal layers 31, 32, 33 are used for shielding against electromagnetic interference. Since Cu cannot tightly adhere to the resin substrate 30, and Cu and Ni are both easily corroded, the first metal layer 31 of Ni formed between the substrate 30 and the second metal layer 32 of Cu improves the adhesion between the substrate 30 and the Cu layers, and the upper most third metal layer 33 of stainless steel protects the inner metal layers 31, 32 from corrosion.

In other embodiments by alternately sputter depositing the metal layers 31, 32, 32 multiple number of times in a predetermined sequence, a multi-layer metal coating can be formed on the substrate 30, providing a better functioning shield against electromagnetic interference.

Other target materials can be used in the process in place of Ni, Cu, and stainless steel, such as silver, metal alloy, and other electrically conductive materials. The substrate 30 can also be made from other materials, such as metal, ceramic, or a metal/polymer composite.

In the magnetron sputtering process described above for deposition of the metal layers 31, 32, 33 onto the resin substrate 30, the travel of electrons ejected from the targets 10, 10′, 10″ is elongated by the magnetic fields, and a collision ratio between electrons and gas molecules is increased, thus ionization of gas and an ion density of incidence to the targets 10, 10′, 10″ are enhanced, so that a high depositing rate of the target materials is obtained, and atoms of the target materials ejected from the targets 10, 10′, 10″ strike the resin substrate 30 with high energy and thus form thereon substantially uniform layers, even though the surface of the substrate 30 is uneven or has recesses. Furthermore, the atoms of the target materials strike the resin substrate 30 with high energy and so are inserted a certain depth into the inner configuration of the substrate 30, whereby, a good adhesion of the metal layers 31, 32, 33 to the surface of the substrate 30 is acquired. Additionally, no secondary electrons bombard the substrate 30 using a magnetron sputtering process, thus the temperature of the resin substrate 30 can keep to a relatively low degree so that the substrate 30 will not have any deformation during sputter deposition.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A method of manufacturing an electromagnetic interference shield comprising the steps of:
(1) preparing a substrate and at least one target module, and mounting them in a sputtering chamber, wherein each target module has a target bonded thereto, and said target is made from an electrically conductive material;
(2) evacuating the sputtering chamber to a predetermined degree of vacuum;
(3) introducing a working gas into the sputtering chamber to a predetermined gas pressure level;
(4) applying a voltage to the target module using a power supply, thus activating a magnetron sputtering process between the target module and the substrate, and depositing at least one electrically conductive layer from the target module onto the substrate until a desired thickness is achieved on the substrate.

2. The method as claimed in claim 1, wherein said degree of vacuum is to be controlled in a range of 10⁻⁸ to 10^{31 4} torr.

3. The method as claimed in claim 1, wherein said gas pressure level is maintained in a range of 10⁻³ to 10⁻¹ torr.

4. The method as claimed in claim 1, wherein a flow rate of said working gas is controlled to be between 2 and 80 SCCM.

5. The method as claimed in claim 1, wherein said power source is a direct current power source.

6. The method as claimed in claim 1, wherein said voltage between the target module and the substrate is in a range between 200 and 1000 volts, and a power density of the target is in a range between 20 and 70 W/cm².

7. The method as claimed in claim 1, wherein said electrically conductive layer is a metal layer.

8. The method as claimed in claim 7, wherein the target is made from nickel.

9. The method as claimed in claim 7, wherein the target is made from copper.

10. The method as claimed in claim 7, wherein the target is made from stainless steel.

11. The method as claimed in claim 1, wherein the target is a composite target, which is divided into a plurality of portions, each portion being made from different electrically conductive materials.

12. The method as claimed in claim 11, wherein said composite target is divided into three portions respectively made from nickel, copper and stainless steel.

13. The method as claimed in claim 1, wherein said substrate is made from resin.

14. The method as claimed in claim 13, wherein said resin has at least one component selected from the group of polyvinyl chloride, polyethylene terephthalate, acrylonitrile-butadiene-styrene, polycarbonate, polyimide, polyetherimide, polyphenylene sulfide, polysulfone, polystyrene, glycol-modified polyester, polypropylene, and liquid crystal polymers.

15. A method of manufacturing an electromagnetic interference shield comprising the steps of:
(1) preparing a substrate and at least one target module, and mounting them in a sputtering chamber, wherein each target module has a target bonded thereto, and said target is made from an electrically conductive material;
(2) controlling the chamber in a designated air pressure level; and
(3) applying a voltage to the target module using a power supply, thus activating a magnetron sputtering process between the target module and the substrate, and depositing at least one electrically conductive layer from the target module onto the substrate until a desired thickness is achieved on the substrate.
